(19) United States
(12) Patent Application Publication
(10) Pub. No.: US 2012/0313111 A1
(43) Pub. Date: Dec. 13, 2012

(54) DIE ALIGNMENT WITH CRYSTALLOGRAPHIC AXES IN GaN-ON-SiC AND OTHER NON-CUBIC MATERIAL SUBSTRATES

(75) Inventors: Robert B. Hallock, Newton, NH (US); Paul M. Head, Dedham, MA (US)

(73) Assignee: Raytheon Company, Waltham, MA (US)

(21) Appl. No.: 13/154,968

(22) Filed: Jun. 7, 2011

(51) Int. Cl. H01L 29/12; H01L 21/78

(52) U.S. Cl. 257/77; 257/76; 257/499; 438/460; 257/E29.068; 257/E21.599

(57) ABSTRACT

A semiconductor chip comprises: a semiconductor structure having a single crystal substrate having a non-cubic crystallographic structure and epitaxial layers disposed on the substrate wherein adjacent sides of the semiconductor structure are at oblique angles. A method for separating a plurality of integrated circuit chips. The method includes: providing a semiconductor wafer having single crystal substrate, such substrate having a non-cubic crystallographic structure with an epitaxial layer disposed on the substrate; forming scribe lines at oblique angles to one another in the epitaxial layer; and cutting or cleaving through the substrate along the scribe lines to separate the chips.

### TECHNICAL FIELD

This disclosure relates generally to semiconductor die and more particularly to semiconductor die having non-cubic crystallographic substrates.

### BACKGROUND

As is known in the art, integrated circuits based on Si, GaAs, InP, and other semiconductors are traditionally laid out in rectilinear patterns on the semiconductor wafers. These wafers are single crystals with cubic crystal structures and the crystallographic directions in the plane of the wafer are at 90° angles, which enables scribe and break separation of die with very smooth edges.

More recently, GaN has emerged as the preferred epitaxial material for many applications. In particular, AlGaN/GaN HEMTs grown as epitaxial layers on SiC substrates are incorporated into MMICs (i.e., monolithic microwave integrated circuits having a plurality of transistors, and arranged, for example, formed on a single chip, sometimes also referred to herein as a die) for radar and other multifunction systems. GaN and SiC have hexagonal crystal structures and are therefore fundamentally different from Si, GaAs, InP and other cubic semiconductors with respect to the orientation of the crystallographic axes on the surface of the semiconductor wafer. Hexagonal wafers such as GaN and SiC are typically cut perpendicular to the c-axis as shown in FIG. 1, so that the crystallographic axes in the plane of the wafer are oriented at 60° and 120° angles, rather than 90° angles, as shown in FIG. 1. More particularly, as described in “Elements of X-Ray Diffraction” by B. D. Cullity, Addison-Wesley 1978, three vectors, a1, a2, & c are sufficient to express crystallographic directions, but an additional vector a3 is commonly used in hexagonal systems as shown. Crystallographic directions and planes are commonly identified using Miller (hkl) or Miller-Bravais (hkil) indices where [hkl] or [hkil] is a direction, <hkl> or <hkil> is a “form” of symmetrically related directions, (hkl) or (hkil) is a plane, and {hkl} or {hkil} is a “form” of symmetrically related planes.

Despite the fact that the crystallographic axes in GaN and SiC are hexagonal and oriented at 60° and 120° angles, MMIC circuits are traditionally laid out in rectilinear patterns. This precludes the use of “scribe and break” techniques used with cubic structures to give very smooth edges on GaN die (i.e., chips), because the natural cleavage planes for both GaN and the underlying SiC substrate are not aligned with the “streets” or scribe lines that separate MMIC die in the layout. The consequence of this misalignment of MMIC layout and scribe lines with the crystallographic cleavage planes in GaN and SiC is that the MMIC die must be singulated (i.e., separated) with a mechanical sawing process which is time consuming, may damage the material, requires wider streets, and results in die with rough edges. The rough edges are particularly undesirable for high frequency applications that have tight tolerances on MMIC dimensions.

### SUMMARY

In accordance with one embodiment of the disclosure, a semiconductor chip comprises: a semiconductor structure having a single crystal substrate having a non-cubic crystallographic structure and epitaxial layers disposed on the substrate wherein adjacent sides of the semiconductor structure are at oblique angles.

In one embodiment, an integrated circuit is formed in the epitaxial layers.

In one embodiment, the substrate is SiC.

In one embodiment, the epitaxial layer includes a layer of GaN on the substrate.

In one embodiment, the epitaxial layer includes a layer of AlGaN on the GaN.

In one embodiment, the epitaxial layer includes a layer of InAlN on the GaN.

In one embodiment, the non-cubic crystallographic structure is a hexagonal crystallographic structure.

In one embodiment, a pair of the sides of the semiconductor structure is at a 60-degree angle.

In one embodiment, a pair of the sides of the semiconductor structure is at a 120-degree angle.

In one embodiment, the semiconductor structure is an equilateral triangular shape.

In one embodiment, the semiconductor structure is a parallelogram shape.

In one embodiment a method is provided method for separating a plurality of integrated circuit chips. The method includes: providing a semiconductor wafer having single crystal substrate, such substrate having a non-cubic crystallographic structure with an epitaxial layer disposed on the substrate; forming scribe lines at oblique angles to one another in the epitaxial layer; and cutting (here cleaving) through the substrate along the scribe lines to separate the chips.

With such structure and method, GaN MMICs are fabricated on AlGaN/GaN epitaxial layers grown on single crystal SiC substrates. The substrates can be of different polytypes (ex: 4H, 6H) with different stacking sequences, but they are hexagonal in structure and are cut or cleaved along crystallographic axes. Scribe and break techniques are used to separate the chips rather then mechanical sawing. The resulting chips have smooth, mirror-like sides.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a diagram of a hexagonal crystal structure, such diagram being useful in understanding crystallographic axis, directions and planes of the structures;

FIG. 2 is a plan view of a semiconductor wafer having a cubic crystallographic structure and having a plurality of chips therein defined by scribe lines formed on the wafer in accordance with the disclosure;

FIGS. 3A-3C are side cross sectional views of a portion of the wafer of FIG. 2 at various stages in the separation of the chips;

FIG. 4 is a top view of a typical one of the transistors adapted for fabrication on the integrated circuit chip of FIG. 2;

FIG. 5 is a top view of an exemplary one of the integrated circuit chips of FIG. 2, such integrated circuit chip having a multi-stage power amplifier, each stage having a plurality of transistors;

FIG. 5A is a perspective view of the exemplary one of the chips of FIG. 5;

FIG. 6 is a diagram showing the scribe lines formed in the wafer of FIG. 2 relative to crystallographic axis of the wafer in accordance with the disclosure;

FIG. 7 is a plane view of a semiconductor wafer having a cubic crystallographic structure and having a plurality of chips therein defined by scribe lines formed on the wafer in accordance with another embodiment of the disclosure;

FIG. 8 is a top view of an exemplary one of the integrated circuit chips of FIG. 7, such integrated circuit chip having a multi-stage power amplifier, each stage having a plurality of transistors; and

FIG. 9 is a diagram showing the scribe lines formed in the wafer of FIG. 7 relative to crystallographic axis of the wafer in accordance with the disclosure.

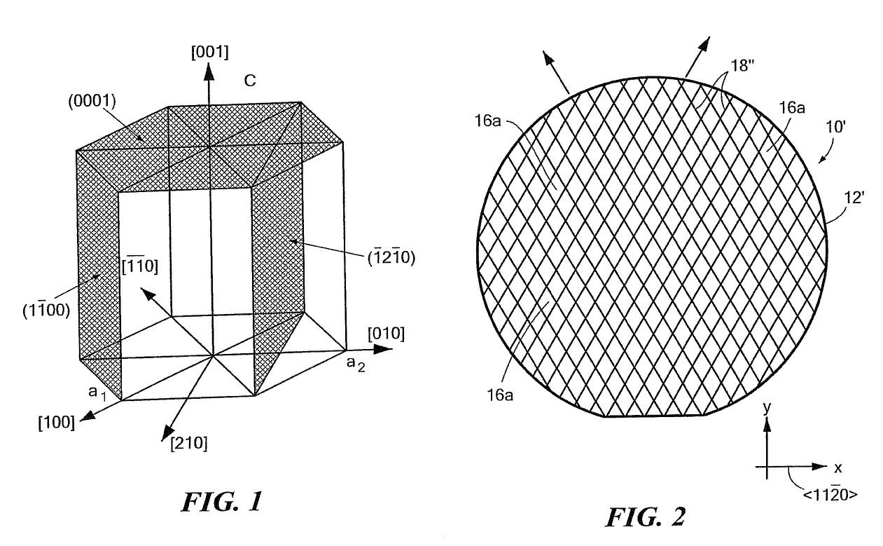

Like reference symbols in the various drawings indicate like elements.

### DETAILED DESCRIPTION

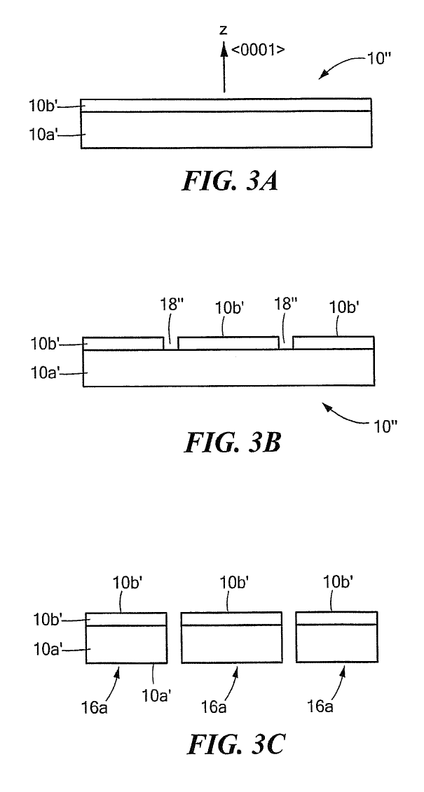

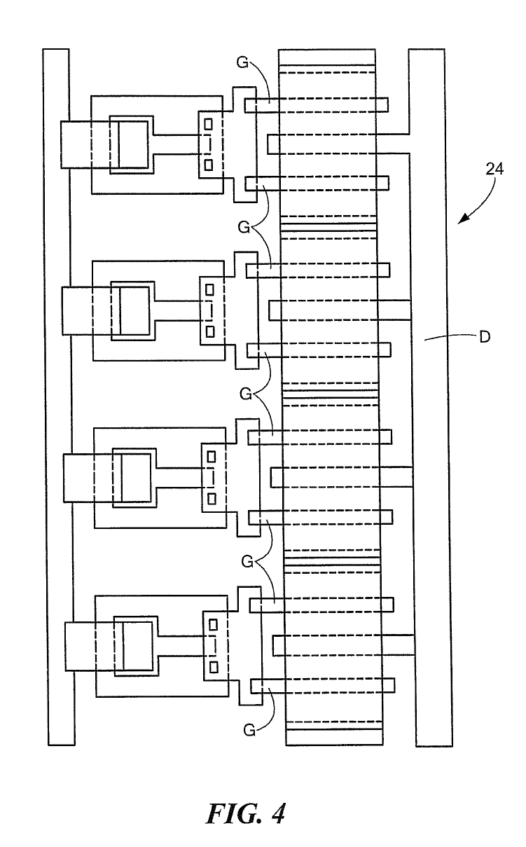

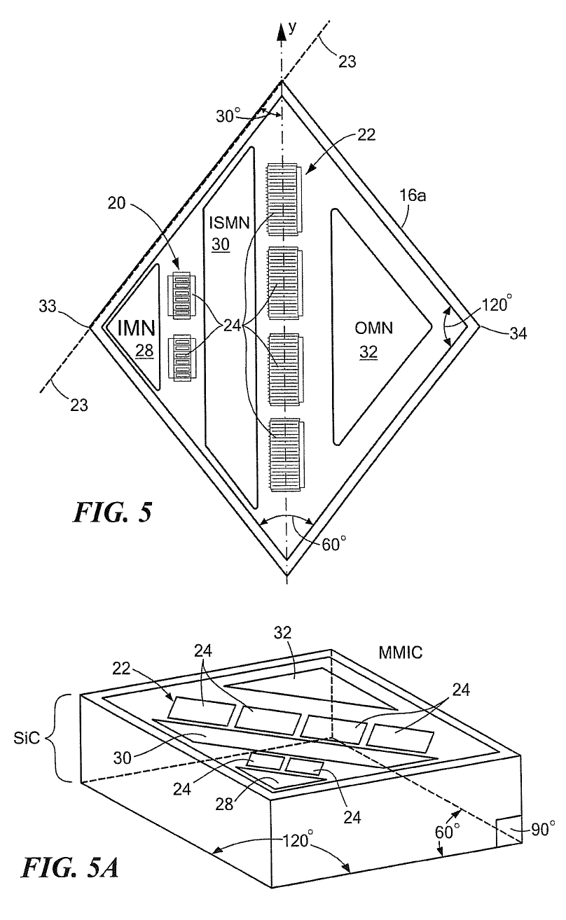

Referring now to FIG. 2, a semiconductor wafer 10′ is shown. Here the wafer 10′ has a hexagonal crystal substrate 10a′ (SiC) with an epitaxial layer 10b′ formed on the surface thereof (FIG. 3A). Here, the epitaxial layer 10b′ is GaN and may have additional epitaxial layers such as AlGaNor InAlN combined with GaN layer; in either case, the additional layers and/or the GaN are referred to herein collectively as epitaxial layer 10′b. Thus, the surface of the wafer 10′ is in the X-Y plane here the {0001} crystallographic plane and the epitaxial layer 10b′ is grown along the Z here <0001> crystallographic axis. The wafer 10′ also has an indication of crystallographic orientation such as a notch or here a truncated circular peripheral portion 12′ along the X axis (i.e., here truncated along the <11 2̅0> crystallographic axis, here along the X axis. An integrated circuit, such as the power amplifier 24 (FIG. 4) is formed in the epitaxial layer 10b′; one integrated circuit for each chip 16a to be obtained from the wafer 10′. Each one of the integrated circuit chips 16a, is identical in construction, an exemplary one thereof, here a parallelogram shaped chip, being shown in FIG. 5. It is noted that the sides of the integrated circuit chip 16a are at 60 degrees and 120 degrees, as indicated. Each one of the integrated circuit chip 16a includes a plurality of serially or cascade coupled sets, here two sets 20, 22 of transistors, here for example, FETs 24 (a typical finger-like gate transistor structure, here the structure described in U.S. Pat. No. 6,232,840 being shown in FIG. 4) arranged to provide a multi-stage, here a two stage power amplifier having an input matching network (IMN) 28 (FIG. 5), which would typically include a power divider circuit distributing a signal at an input to the control electrode, here gate electrodes, G, of a first stage (i.e., set 20) of the transistors; an inter-stage matching networks (ISMN) 30 which would typically include a second power divider circuit distributing power at the output (here, drain electrode, D) of the first stage to inputs (here, control electrodes (gate electrodes, G)) of the second stage; and an output matching network 32 (OMN) which would typically include a power combiner combing power at the drain electrode, D, of the second stage (i.e., set 22) to output of the amplifier. It should be understood that more than two stages may be used. In such case, more gain stages comprising additional pluralities of transistors are disposed on the integrated circuit chip and distributed parallel to the axis along which the above-described plurality of transistors is distributed. Each one of the transistors in the additional pluralities of transistors would also have a plurality of parallel control electrodes extending longitudinally along an axis perpendicular to the axis along which the plurality of transistors is distributed.

Each one of the two stages 20, 22 each includes a plurality of the transistors 24, the transistors 24 in each set 20, 22 being distributed along an axis, here indicated as the Y-axis. The Y-axis is, as noted above, at an oblique angle, here 30 degrees, as indicated, to a pair of opposing sides of the integrated circuit chip. Thus, the plurality of transistors is disposed on the integrated circuit chip and distributed along an axis, i.e., the Y axis, making an oblique angle with respect to an axis 23 passing through a side of the integrated circuit chip. Thus, the plurality of transistors is disposed on the integrated circuit chip along an elongated dimension of the chip.

Here, the first stage 20 has two of the FETs 24 and the second stage 22 includes four of the FETs 24. In each stage 20, 22, the FETs 24 therein include a plurality of finger-like control electrodes, here finger-like gate electrodes, G, (FIG. 3) which extend in parallel longitudinally along an axis perpendicular to the Y-axis along which the plurality of transistors 24 is distributed (i.e., here the finger-like gate electrodes G extend long the X-axis). It shown be noted that the power-handling requirement of the transistors in set 22 is greater than the power-handling requirement of the transistors in set 20. Therefore, the size of the transistors in set 22 is larger than the transistors in set 20.

The input-matching network (IMN) 28 is disposed on the integrated circuit chip between a corner 33 of the integrated circuit chip 16a and the plurality of transistors in the input stage (i.e., set 20). The output-matching network (OMN) 32 is disposed between an opposing corner 34 of the integrated circuit chip and the plurality of transistors in the second stage (i.e., set 22).

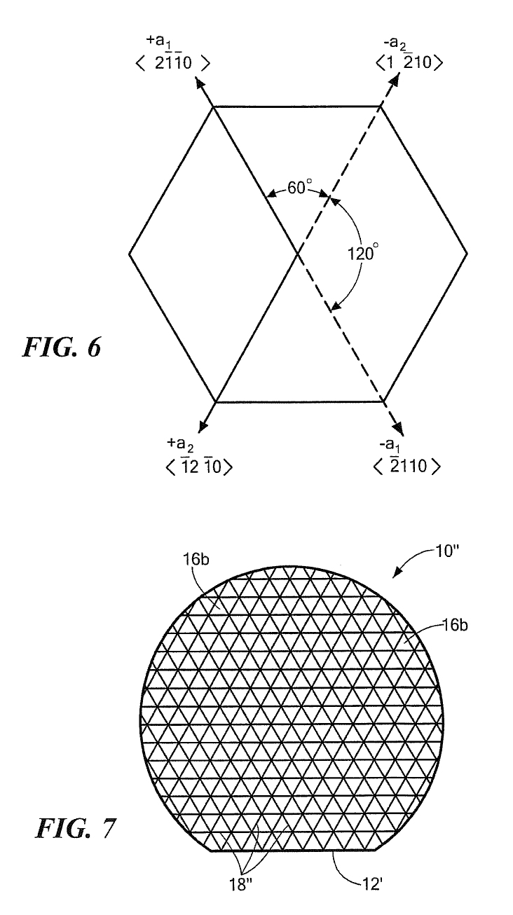

Next, the integrated circuit chips 16a are formed by etching scribe lines 18″ through the epitaxial layer 10b′ as indicated in FIG. 2. More particularly, the scribe lines 18″ (FIG. 2) are along two of the crystallographic axis directions (FIG. 6); here, the <11 2̅0> axis direction and the < 1̅2 1̅0> axis direction, as indicated. It is noted that these directions are at 60 degree and 120 degree angles, as indicated.

After scribe lines 18′ are formed through the epitaxial layer 10b′ (FIG. 3B) along two of the three crystallographic axis: here, the <2 1̅ 1̅0> axis and the < 1̅2 1̅0> axis, the chips 16a; are separated one from the other by, for example, any conventional scribe and break technique cutting along the scribe lines 18′ through the underlying portions of the substrate 10a′ (FIG. 3C); an exemplary one of the chips 18′ being shown in FIGS. 5A and 5B. Here, for example, the scribe lines 18′ are formed with a diamond tip (although other methods such as etching or laser cutting may be used) and the wafer is cleaved along the scribe lines 18′ to singulate (i.e., separate).

It is noted that by cutting along the <2 1̅ 1̅0> axis, the < 1̅2 1̅0> axis and the <11 2̅0> axis the sides of the chips 16a′ are in the {10 1̅0} plane form thereby providing the chips 16a with smooth, mirror-like edges.

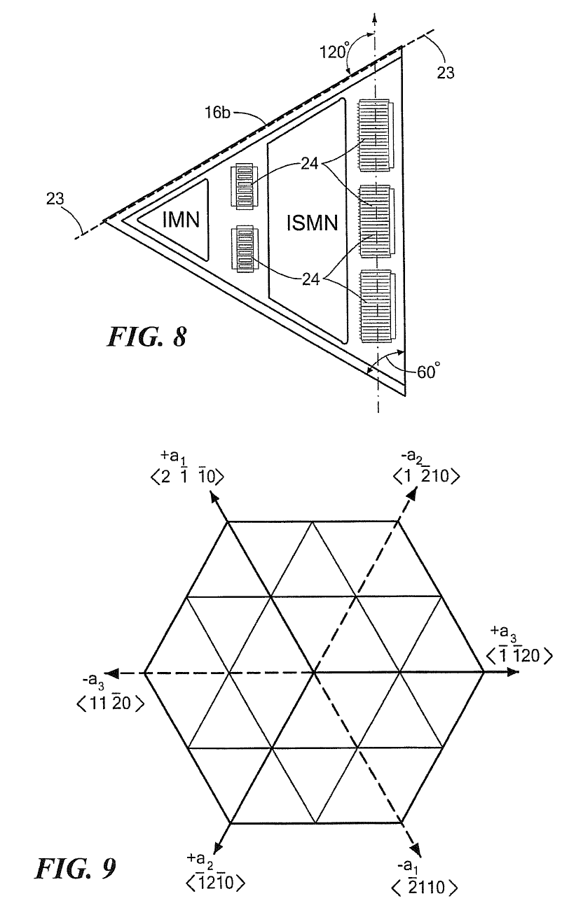

Referring now to FIG. 7, a wafer 10″ is shown. Here the wafer 10″ has a hexagonal crystal substrate (e.g., SiC) with an epitaxial layer formed on the surface thereof as described above in connection with FIG. 2A. Thus, the surface of the wafer 10″ is in the X-Y plane here the {0001} crystallographic plane and the epitaxial layer 10b′ is grown along the Z here <0001> crystallographic axis. The wafer 10″ is also has a truncated circular peripheral portion 12′ along the X axis (i.e., here truncated along the <11 2̅0> crystallographic axis, here along the X axis. An integrated circuit, such as the power amplifier 24 (FIG. 8) is (except for the OMN) formed in the epitaxial layer 10b′; one integrated circuit for each chip 16b to be obtained from the wafer 10″.

Each one of the integrated circuit chips 16b, is identical in construction, an exemplary one thereof, here an equilateral triangular shaped chip, being shown in FIG. 8.

Next, equilateral triangular shaped integrated circuit chips 16b are formed by etching scribe lines 18″ though the epitaxial layer 10b′.

More particularly, the scribe lines 18′ are along three crystallographic axis directions: the <2 1̅ 1̅0> axis, the < 1̅2 1̅0> axis and the <11 2̅0> axis, as indicated in FIG. 9. It is noted that the direction of the <2 1̅ 1̅0> axis and the direction of the axis < 1̅2 1̅0> form 60 and 120 degree angles; and the direction of the < 1̅2 1̅0> axis and the direction of the <11 2̅0> axis form 60 and 120 degree angles, and the direction of the <2 1̅ 1̅0> axis and the direction of the <11 2̅0> axis form a 60 and 120 degree angles. Thus, the scribe lines 18′ are at 60 degree angles

After scribe lines 18″ are formed through the epitaxial layer 10b′ along the three crystallographic axis: the <2 1̅ 1̅0> axis, the < 1̅2 1̅0> axis and the<11 2̅0> axis, the equilateral triangular shaped chips 16b; are separated one from the other by, for example, any conventional scribe and break technique cutting along the scribe lines 18″ though the underlying portions of the substrate 10a′; an exemplary one of the chips 16b being shown in FIG. 8. It is noted that by cutting along the <2 1̅ 1̅0> axis, the < 1̅2 1̅0> axis and the <11 2̅0> axis the sides of the chips 18b are in the {10 1̅0} plane form thereby providing the triangular shaped chips 18 with smooth, mirror-like edges.

It is noted that with both the triangular shaped chips and the parallelogram shaped chips, the transistors are aligned along an axis at an obtuse angle with respect to a side of the chip; and thus the transistors are distributed along an elongated dimension of the polygon (i.e., the triangle or the parallelogram).

A number of embodiments of the disclosure have been described. Nevertheless, it will be understood that various modifications may be made without departing from the spirit and scope of the disclosure. For example, the shape may be trapezoidal. Accordingly, other embodiments are within the scope of the following claims.

What is claimed is:

1. A semiconductor chip, comprising:
a semiconductor structure, comprising:
a single crystal substrate having a non-cubic crystallographic structure;
and
epitaxial layers disposed on the substrate; and
wherein adjacent sides of the semiconductor structure are at oblique angles.

2. The semiconductor chip recited in claim 1 wherein an integrated circuit is formed in the epitaxial layer surface.

3. The semiconductor chip recited in claim 2 wherein the substrate is SiC.

4. The semiconductor chip recited in claim 3 wherein the epitaxial layer includes a layer of GaN on the substrate.

5. The semiconductor chip recited in claim 4 wherein the epitaxial layer includes additional layers AlGaNor InAlNon the GaN.

6. The semiconductor chip recited in claim 1 wherein the non-cubic crystallographic structure is a hexagonal crystallographic structure.

7. The semiconductor chip recited in claim 6 wherein a pair of the sides of the semiconductor structure is at a 60-degree angle.

8. The semiconductor chip recited in claim 6 wherein a pair of the sides of the semiconductor structure is at a 120-degree angle.

9. The semiconductor chip recited in claim 6 wherein the semiconductor structure is an equilateral triangular shape.

10. The semiconductor chip recited in claim 6 wherein the semiconductor structure is parallelogram shaped.

11. The semiconductor chip recited in claim 6 wherein an integrated circuit is formed in the epitaxial layer.

12. The semiconductor chip recited in claim 6 wherein the substrate is SiC.

13. The semiconductor chip recited in claim 6 wherein the epitaxial layer includes a layer of GaN on the substrate.

14. The semiconductor chip recited in claim 11 wherein a pair of the sides of the semiconductor structure is at a 60-degree angle.

15. The semiconductor chip recited in claim 11 wherein a pair of the sides of the semiconductor structure is at a 120-degree angle.

16. The semiconductor chip recited in claim 11 wherein the semiconductor structure is an equilateral triangular shape.

17. The semiconductor chip recited in claim 11 wherein the semiconductor structure is parallelogram shaped.

18. A semiconductor chip, comprising:
a semiconductor structure, comprising:
a single crystal substrate having a non-cubic crystallographic structure;
and
an epitaxial layer disposed on the substrate; and
wherein adjacent sides of both the epitaxial layer and substrate are at oblique angles.

19. The semiconductor chip recited in claim 18 wherein an integrated circuit is formed in the epitaxial layer surface.

20. A method for separating a plurality of integrated circuit chips, comprising:
providing a semiconductor wafer having single crystal substrate, such substrate having a non-cubic crystallographic structure with epitaxial layers disposed on the substrate;
forming scribe lines at oblique angles to one another in the epitaxial layer; and
cutting through the substrate along the scribe lines to separate the chips.

21. The method recited in claim 20 including forming a plurality of integrated circuits in the epitaxial layer prior to the separating.

22. The method recited in claim 20 wherein a pair of the scribe lines is formed at a 60-degree angle.

23. The method recited in claim 20 wherein a pair of the scribe lines is formed at a 120-degree angle.

24. The method recited in claim 20 wherein the chips are formed as equilateral triangular shaped chips.

25. The method recited in claim 20 wherein the chips are formed as parallelogram shaped chips.

26. The semiconductor chip recited in claim 1 wherein adjacent sides of the semiconductor structure are along crystallographic axes of the substrate.

27. The method recited in claim 20 wherein the cutting is along crystallographic axes of the substrate.
